(19) United States
(12) Patent Application Publication
(10) Pub. No.: US 2024/0372049 A1
(43) Pub. Date: Nov. 7, 2024

(54) PRODUCTION METHOD FOR A CHIP-TYPE LAMP BEAD CAPABLE OF EMITTING POLYCHROMATIC LIGHT

(71) Applicant: Ji'an Mulinsen Components Co., Ltd., Ji'an (CN)

(72) Inventors: Caixiang Zhou, Ji'an (CN); Lijun Liu, Ji'an (CN); Meizhong Xiong, Ji'an (CN); Wenxin Huang, Ji'an (CN); Nana Zou, Ji'an (CN)

(73) Assignee: Ji'an Mulinsen Components Co., Ltd., Ji'an (CN)

(21) Appl. No.: 18/771,577

(22) Filed: Jul. 12, 2024

(30) Foreign Application Priority Data
Mar. 20, 2024 (CN) 202410322264.2

(51) Int. Cl. H01L 33/58

(52) U.S. Cl. CPC H01L 33/58; H01L 2933/0058; H01L 2933/0083

(57) ABSTRACT

A production method for a chip-type lamp bead capable of emitting polychromatic light relates to the technical field of LED lamp beads, including steps: a first process: die bonding, for fixing a chip to a supporting plate; a second process: wire bonding, for linking positive and negative electrodes of the chip to a bracket; a third process: molding, for packaging the material with an epoxy resin after prior two steps, and different light colors are achieved through matching with different phosphors; a fourth process: cutting, for cutting the molded material into single materials; a fifth process: light splitting, for splitting light in the material having been cut; and a sixth process: braiding, packaging and shipping. Multiple LED chips can be integrated inside a chip-type lamp bead, each chip can emit light independently and control different colors, and thus the same lamp bead can achieve free mixing of multiple colors.

### CROSS-REFERENCE TO RELATED APPLICATIONS

The application claims priority to Chinese patent application No. 202410322264.2, filed on Mar. 20, 2024, the entire contents of which are incorporated herein by reference.

### TECHNICAL FIELD

The present disclosure relates to the technical field of LED (light-emitting diode) lamp beads, in particular to a production method for a chip-type lamp bead capable of emitting polychromatic light.

### BACKGROUND

With the continuous deepening of technology and environmental protection concepts, LED lamp beads have become a mainstream choice for the global lighting and display industry due to their unrivalled advantages. The LED lamp beads are excellent in energy saving, with their much lower energy consumption than traditional lighting sources, and their characteristics of long lifetime and short response time make them widely used in many scenes. From general lighting in homes and commercial places to advanced lighting solutions of automotive interior and exterior; from high-definition display of large display screens to precise control of traffic signal indication systems, and to the delicate performance of backlighting in consumer electronics, the LED lamp beads play a key role therein.

At present, when an LED chip is packaged, due to multiple factors such as packaging effect, electric current transmission, and smoothness of pin hole, a flowing direction of the packaging glue used in package cannot flow to electrode plates on both sides of a LED lamp bead bracket, but can only flow in a direction vertical to the electrode plates on both sides, which can ensure that the packaging glue covers a surface of the LED chip, forming an effective protective layer, and avoiding affections on the current transmission and the smoothness of the pin hole.

Since the electrode plates of the LED lamp bead bracket are distributed in half on opposite sides of the bracket, when a single or multiple LED chips configured on the electrode plates are packaged by dispensing, only a unified packaging method can be used. Once the multiple LED chips are packaged independently, gold wires used for welding the LED chips and the electrode plates will be exposed outside a packaging material, which is easy to cause damages. This means that no matter how many the LED chips are configured on the electrode plates, they will be covered by the same packaging material and cannot be packaged independently, and the same packaging material has only one color, thus that an LED lamp bead can only emit light of one color and cannot emit light of multiple colors.

The present disclosure aims to solve the problem that the present chip-type lamp bead can only be molded with one color, and if two colors are needed, chips are used to emit light, and the packaging material cannot be used for debugging.

### SUMMARY

In order to solve the problem that the present chip-type lamp bead can only be molded with one color, and if two colors are needed, chips are used to emit light, and the packaging material cannot be used for debugging, the present disclosure adopts the following technical solutions:

A production method for chip-type lamp bead capable of emitting polychromatic light comprises the following processes:
a first process: die bonding, for fixing a chip is to a supporting plate;
a second process: wire bonding, for linking positive and negative electrodes of the chip to the bracket;
a third process: molding, for packaging the material with an epoxy resin after die bonding and wire bonding, and different light colors are achieved through matching with different phosphors;
a fourth process: cutting, for cutting the molded material into a single material according to size requirements;
a fifth process: light splitting, for splitting light in the material having been cut according to customers' requirements; and
a sixth process: braiding, packaging and shipping.

Preferably, the first process further comprises the following steps:
ensuring that a special mark (green oil points) on the supporting plate in the process of die bonding through a PR (Picture Recognition) technology and ensuring that the first LED chip is fixed according to the predetermined position, that is, the direction of the green oil points; wherein the supporting plate is a raw material of the bracket, and multiple brackets are formed after the supporting plate is cut.

Preferably, the third process further comprises the following steps:
an operator receives a glue compound formed by the packaging material and then places it into a mold hole on a ready molding mold; before the molding operation, an upper mold and a lower mold of the molding machine are uniformly sprayed with a parting agent to ensure that the packaging material does not adhere to the mold when it is in contact with the mold, so as to facilitate subsequent separation; during the molding operation, the bracket is upended and placed on the lower mold of the molding mold at first, and then the upper mold and the lower mold are pressed and heated to melt the glue compound to form a glue mixture, and the glue mixture flows to and covers LED chips; when the temperature of the mold drops and the glue solidifies, the mold can be opened to remove the material.

Preferably, the molding mold comprises the lower mold, the lower mold further comprises a first molding area and a second molding area, and a structure of each part of the second molding area and the first molding area are the same. The first molding area comprises a first supporting plate placement area and a second supporting plate placement area.

Preferably, the first molding area comprises a first glue compound hole and a second glue compound hole, the first glue compound hole and the second glue compound hole are provided on a top surface of the lower mold, the first glue compound hole is used for placing a first color glue compound, the second glue compound hole is used for placing a second color glue compound. The first glue compound hole and the second glue compound hole are located between the first supporting plate placement area and the second supporting plate placement area, the lower mold is provided with a first main glue channel at both sides of the first glue compound hole, the lower mold is provided with multiple first secondary glue channels at one side of the first main glue channel, and the first main glue channel is communicated with the first secondary glue channel. The lower mold is provided with a second main glue channel at both sides of the second glue compound hole, the lower mold is provided with multiple second secondary glue channels at one side of the second main glue channel, and the second main glue channel is communicated with the second secondary glue channel.

Preferably, the lower mold is provided with an exhaust hole at one end of both the first secondary glue channel and the second secondary glue channel.

Preferably, four corners of the supporting plate are provided with positioning holes, and the positioning holes are correspondingly placed on the molding mold for preventing the deviation of the bracket, and the positioning holes on both sides of the supporting plate are arranged asymmetrically for preventing the supporting plate from being reversed.

Preferably, a single material cut in the fourth process includes LED lamp beads, where in the LED lamp bead includes a bracket, the bracket provides a basis for physical support and electrical conduction of the entire LED lamp bead. One side of a top surface of the bracket is fixedly connected with a first electrode plate, the other side of the top surface of the bracket is fixedly connected with a second electrode plate, the first electrode plate and the second electrode plate are nested and arranged with each other, and the first electrode plate and the second electrode plate are both fixedly connected with a LED chip, and the first electrode plate and the second electrode plate are both electrically connected with the LED chip. A packaging material is fixedly connected above the LED chip, the packaging material is fixedly connected with the bracket, and the packaging material is used to cover and protect the LED chip.

Preferably, an overall shape of the first electrode plate and the second electrode plate is a L-shape, one end of the first electrode plate faces one side of the second electrode plate, the other side of the second electrode plate faces the other end of the first electrode plate, and the first electrode plate and the second electrode plate are enclosed to form a rectangle shape.

Preferably, the packaging material is a transparent epoxy resin, and a phosphor with color is mixed into the packaging material.

Compared with the prior arts, the present disclosure has the following beneficial effects.

1. In the present disclosure, multiple LED chips connected in parallel can be integrated inside a chip-type lamp bead. Each chip can emit light independently and be packaged independently, and each independently packaged LED chip can emit light of different colors depending on the colors of the packaging material, breaking the limitations of the traditional monochrome lamp beads. This innovative design of the present disclosure enables a same lamp bead to achieve free mixing of multiple colors, which greatly expands the application ranges of LED lamp beads in the field of lighting and decoration, especially in occasions where colorful light effects and dynamic changes are required.

2. In the chip-type lamp bead capable of emitting polychromatic light of the present disclosure, multiple LED chips with different colors are integrated inside a single lamp bead and connected in parallel, so that the lighting effect of two or more colors can be achieved by installing only one lamp bead on a lamp string. This innovative design of the present disclosure has greatly improved production efficiency, reduced the quantity of lamp beads that need to be installed, and directly reduced the material costs of the lamp strings. At the same time, due to the reduction of the quantity of the lamp beads, the welding points and potential failure points are also reduced by half accordingly, which not only simplifies the production processes, but also significantly improves the overall yield and reliability of the lamp strings.

3. In the present disclosure, the packaging method of LED lamp beads also makes full use of the existing packaging technology, the LED chips with different spacing can be packaged through adjusting the spacing between the packaging flow channels of the molding mold, without need of greatly improving or upgrading the existing packaging technology, which not only reduces production costs, but also improves production efficiency, thus the LED lamp bead structure of the present disclosure more is competitive in practical applications.

In summary, the present disclosure solves the problem that the chip-type lamp bead bracket can only be molded with one color, and if two colors are required, chips are used to emit light, and the phosphor cannot be used for debugging.

### BRIEF DESCRIPTION OF DRAWINGS

The accompanying drawings described herein are used to provide further understanding of the present disclosure and form a part of the present disclosure, and the illustrative embodiments of the present disclosure and their explanations are used to explain the present disclosure and do not constitute an undue limitation of the present disclosure. In the accompanying drawings:

FIG. 1 is a structural schematic diagram of a chip-type lamp bead produced by a production method for a chip-type lamp bead capable of emitting polychromatic light according to the present disclosure;

FIG. 2 is a structural schematic diagram of a chip-type lamp bead after being packaged of the production method for a chip-type lamp bead capable of emitting polychromatic light according to the present disclosure.

FIG. 3 is a structural schematic diagram of a supporting plate of the production method for a chip-type lamp bead capable of emitting polychromatic light according to the present disclosure.

FIG. 4 is a structural schematic diagram of a lower mold of a production method for a chip-type lamp bead capable of emitting polychromatic light according to the present disclosure.

FIG. 5 is an enlarged structural schematic diagram of part A in FIG. 4.

FIG. 6 is an enlarged structural schematic diagram of part B in FIG. 4.

FIG. 7 is a packaging diagram of an original chip-type bracket.

FIG. 8 is a structural schematic diagram of the original chip-type bracket.

FIG. 9 is a traditional molding mold.

### DETAILED DESCRIPTION OF THE EMBODIMENTS

The technical solutions in the embodiments of the present disclosure will be clearly and completely described with the drawings in the embodiments of the present disclosure. Obviously, the embodiments described are merely some embodiments of the present disclosure, but not all the embodiments.

### Embodiment

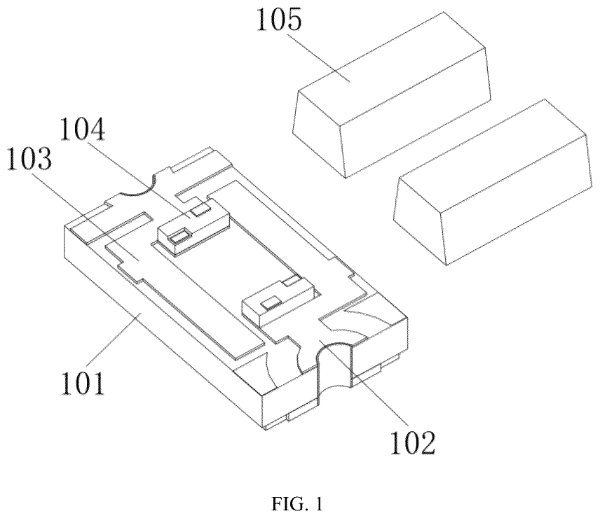

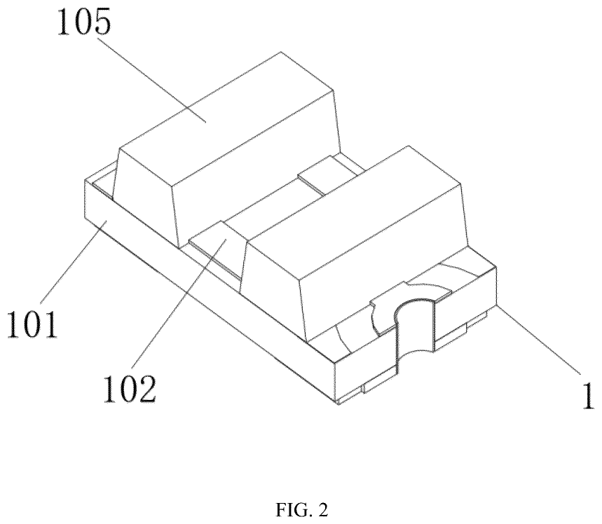

The embodiment of the present disclosure provides a chip-type lamp bead structure capable of emitting polychromatic light, as shown in FIGS. 1 to 2, comprising an LED (light-emitting diode) lamp bead 1, wherein the LED lamp bead 1 comprises a bracket 101, and the bracket 101 provides a basis for physical support and electrical conduction of the entire LED lamp bead 1. One side of a top surface of the bracket 101 is fixedly connected with a first electrode plate 102, the other side of the top surface of the bracket 101 is fixedly connected with a second electrode plate 103, and the first electrode plate 102 and the second electrode plate 103 are configured to be nested with each other. The first electrode plate 102 and the second electrode plate 103 are both fixedly connected with a LED chip 104, and the first electrode plate 102 and the second electrode plate 103 are electrically connected with the LED chip 104. Multiple the LED chips 104 are connected in parallel, a packaging material 105 is fixedly connected above the LED chip 104, the packaging material 105 is fixedly connected with the bracket 101, and the packaging material 105 is used to cover and protect the LED chip 104.

An overall shape of the first electrode plate 102 and the second electrode plate 103 is a L-shape, one end of the first electrode plate 102 faces one side of the second electrode plate 103, the other side of the second electrode plate 103 faces the other end of the first electrode plate 102, and the first electrode plate 102 and the second electrode plate 103 are enclosed to form a rectangle shape.

The packaging material 105 is a transparent epoxy resin, and a phosphor with color is mixed into the packaging material 105.

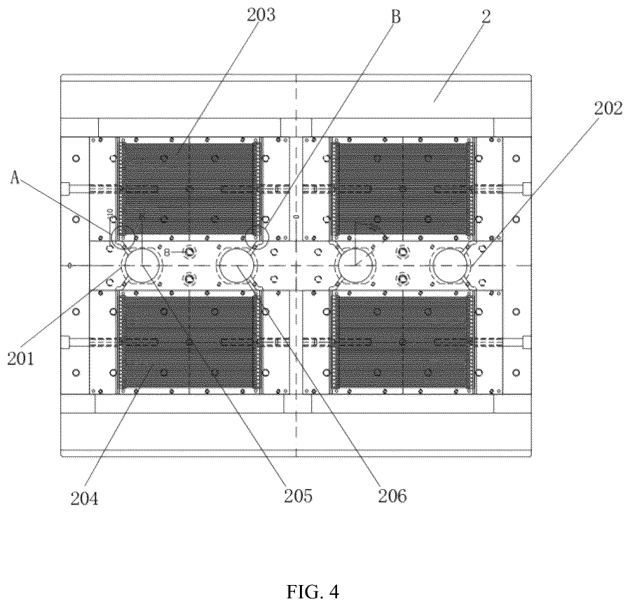

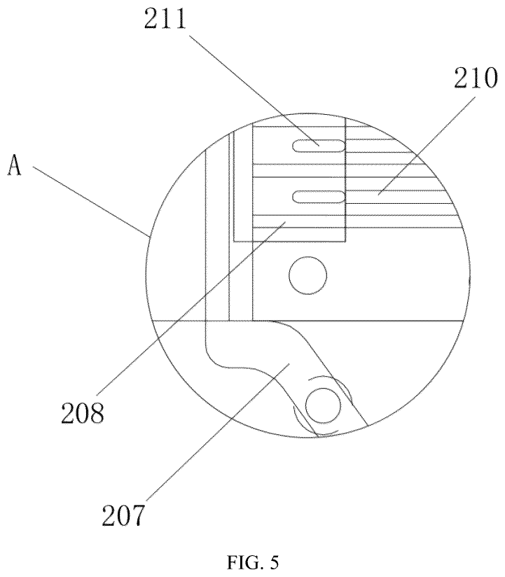

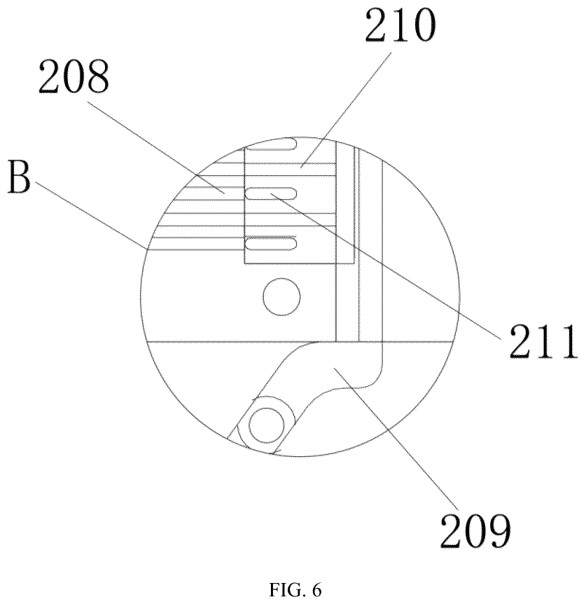

In the specific embodiments, as shown in FIGS. 1 to 11, when an external power supply is connected, an electric current enters the bracket 101 through a pin or a connecting wire of the LED lamp bead. The bracket 101 not only provides physical support for the entire lamp bead structure, but also serves as a basis for electrical conduction to evenly distribute the electric current to the first electrode plate 102 and the second electrode plate 103.

The first electrode plate 102 and the second electrode plate 103 are respectively connected with multiple LED chips 104, these chips are connected in parallel, so that they can independently derive electric current from the electrode plates and emit light of a specific color according to their own characteristics. The advantage of the parallel structure design is that even if a single LED chip has a problem, it will not affect the normal operations of other chips, thus improving the reliability and flexibility of the whole system. If the multiple LED chips 104 are connected in series, when the LED chips 104 are installed face-up, gold wires are required to connect the multiple LED chips 104 in series. Since there are gold wires between the LED chips 104, an independent packaging of one LED chip 104 cannot be achieved. When the LED chips 104 are flipped, that is, an electrode of the LED chip 104 is directly in contact with the electrode plates, and the multiple LED chips 104 cannot be connected in series.

The layout design of the electrode plates breaks through the limitations of distribution in half of the electrode plates of traditional LED lamp bead brackets. The first electrode plate 102 and the second electrode plate 103 are not simply distributed on both sides of the bracket 101, but are nested and staggered mutually. This layout design not only optimizes the space utilization, making it possible to install multiple LED chips 104 on the limited area of the bracket 101, but also provides the possibility for independently packaging each LED chips 104. Since each LED chip 104 can be independently connected with its adjacent electrode plates, the gold wires used for welding the electrode plates after being independently packaged will not be exposed outside the packaging material 105, and this independently package method also makes full use of the existing packaging technology. By adjusting the distances between the packaging flow channels of the molding mold, the packaging of the LED chips with different distances can be achieved without greatly improving or upgrading the existing packaging technology, which not only reduces production costs, but also improves the production efficiency, thus the LED lamp bead structure of the present disclosure is more competitive in practical applications.

When the LED chip 104 emits light, the emitted light passes through the packaging material 105 upwards. The packaging material 105 is typically made of a transparent epoxy resin, which is mixed with a phosphor with color. The phosphor is able to absorb a part of the light emitted by the LED chips and then emit another color of light. Therefore, in the packaging material 105, an original light of the LED chip and a light converted by the phosphor are superimposed and mixed mutually to form a richer and softer color effect. Since multiple independently packaged LED chips 104 are provided on the electrode plates, the LED lamp beads with the lamp bead structure of the present disclosure can emit light of different colors. After the packaging material 105 is mixed and diffused, the multi-color light is emitted from the LED lamp beads through the transparent portion of the packaging material 105 to form a visible polychromatic light effect, which can be used in a variety of lighting and indication applications for providing colorful ambience and visuals to the environment.

The light-emitting colors of the LED chip 104 and the type and ratio of the phosphors in the packaging material 105 can be adjusted according to specific needs, so as to achieve different polychromatic light effects.

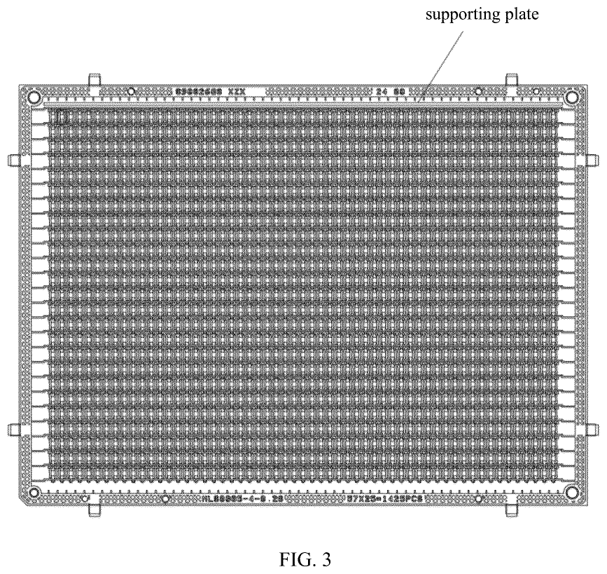

In addition, as shown in FIGS. 3 to 6, the present disclosure further provides a production method for chip-type lamp bead capable of emitting polychromatic light, comprises the following processes:

A first process: die bonding, for fixing a chip to the supporting plate.

Step S11: The supporting plate is dehumidified, which is a process of ensuring that the supporting plate is dry and moisture-free in advance, to avoid moisture affecting the subsequent die bonding effect. In this step, the supporting plate will be continuously dehumidified at a high temperature of 170° C. for 1 hour to fully remove the internal and surface moisture.

Step S12: The supporting plate after being dehumidified will be loaded into a special material box and then sent to a production line for die bonding. During this period, the production equipment will set up a mistake-proofing mechanism to prevent product quality problems caused by operational errors. At the same time, through a PR (Picture Recognition) technology, it is ensured that during die bonding process, the special mark on the supporting plate: such as “a green oil point” is accurately identified, and the first LED chip is fixed according to the predetermined position, that is, the direction of the green oil point, because the green oil point often represents the best die bonding position, which is conducive to improving the luminous efficiency and stability of the lamp beads. The supporting plate is the raw material of the bracket 101, and a plurality of brackets 101 are formed after the supporting plate is cut.

Step S13: During die bonding operation, the same or similar LED chips with different parameters will be arranged in different operation areas for die bonding in order to avoid confusion and ensure product quality. Once the die bonding is completed, the material will be dehumidified again, because a small amount of water may be introduced during die bonding, and the material after being dehumidified will be transferred to the next process: wire bone, so as to ensure the reliable connection between the chip and the electrode of the supporting plate, thereby forming a complete circuit path.

A second process: wire bonding, for linking positive and negative electrodes of the chip to the bracket.

Step S21: The relevant parameters of the wire bond are confirmed carefully before starting the wire bond, including a welding time: 1 to 6 milliseconds, a power required for welding: 40 to 70 watts, and a pressure applied during welding: 15 to 25 MPa, wherein the precise setting of these parameters is critical to the quality of the wire bond and the performance of the lamp beads.

Step S22: The wire bond operation starts after ensuring that all the materials are correct, the material completed wire bond will be stored in a moisture-proof cabinet to wait for the next process, which aims at preventing moisture from affecting the lamp beads completed wire bond, thus to ensure their electrical performance and reliability.

Step S23: In order to ensure the quality of the wire bond, the factory will regularly test the wafer mistake-proofing function of the wire bonding station, and a comprehensive test is conducted by the night shift staff once a week. Without affecting the normal operation, a supporting plate will be selected as a test sample, and all the wire bonding machines on the whole production line are performed a mistake-proofing test in turn through reversing the wire bonding starting unit on the supporting plate. For some types of machines that only contain only single electrodes, there is no need to conduct the mistake-proofing test. However, in any case, as long as it involves the operations of machine debugging, and changing product model replacement or wafer type, it must be verified by the machine mistake-proofing test before starting the operation, so as to prevent errors to the greatest extent, and thus to ensure the smooth of production process and the stability of product quality.

A third process: molding, for packaging the materials with an epoxy resin after die bonding and wire bonding, where in different light colors can be achieved through matching with different phosphors.

Step S31: A technician will adjust the proportion of the phosphors according to the required and color effect to ensure that the correct color can be mixed during the packaging process. After the phosphor is adjusted, the packaging material 105 is made into a glue-compound shape and then passed to an operator for the next step of operation.

Step S32: The operator receives a made glue compound and then places it in a mold hole on a ready molding mold in advance. Before the molding operation, an upper mold and a lower mold 2 of the molding machine are uniformly sprayed with a parting agent to ensure that the packaging material 105 does not adhere to the mold when it is in contact with the molds, so as to facilitate subsequent separations. During the molding operation, the bracket 101 is upended and placed on the lower mold 2 of the molding mold at first, and then the upper mold and the lower mold 2 are pressed and heated to melt the glue compound to form a glue mixture, and the glue mixture flows to and covers the LED chip. When the temperature of the mold drops and the glue solidifies, the mold is opened to remove the material. During the molding operation, a pressure of the molding mold is set at 70 to 150 kg per square centimeter to ensure that the packaging material 105 can fully penetrate and wrap the LED chips; a speed is set in the range of 50 to 100 seconds to ensure that the packaging material 105 solidifies in an appropriate time; and a temperature is controlled at 120° C. to 170° C. to ensure that the packaging material 105 melts and solidifies at an appropriate temperature, thus to form good optical and mechanical properties. Through the above rigorous operations and fine parameter control, the molding process of the LED lamp beads is finally completed.

The molding mold includes a lower mold 2, the lower mold 2 further comprises a first molding area 201 and a second molding area 202, and a structure of each part of the second molding area 202 and the first molding area 201 are the same. The first molding area 201 includes a first supporting plate placement area 203 and a second supporting plate placement area 204.

The first molding area 201 includes a first glue compound hole 205 and a second glue compound hole 206, wherein the first glue compound hole 205 is used for placing a first color glue compound, and a second glue compound hole 206 is used for placing a second color glue compound. The first glue compound hole 205 and the second glue compound hole 206 are provided on a top surface of the lower mold 2, the first glue compound hole 205 and the second glue compound hole 206 are located between the first supporting plate placement area 203 and the second supporting plate placement area 204; the lower mold 2 is provided with a first main glue channel 207 at both sides of the first glue compound hole 205, the lower mold 2 is provided with multiple first secondary glue channels 208 at one side of the first main glue channel 207, and the first main glue channel 207 is communicated with the first secondary glue channel 208. The lower mold 2 is provided with a second main glue channel 209 at both sides of the second glue compound hole 206, the lower mold 2 is provided with multiple second secondary glue channels 210 at one side of the second main glue channel 209, and the second main glue channel 209 is communicated with the second secondary glue channel 210. The lower mold 2 is provided with an exhaust hole 211 at one end of both the first secondary glue channel 208 and the second secondary glue channel 210.

Four corners of the supporting plate are provided with positioning holes, which are correspondingly placed on the molding mold for preventing the deviation of the bracket, and the positioning holes on both sides of the supporting plate are arranged asymmetrically for preventing the supporting plate from being reversed.

A fourth process: cutting, for cutting the molded material into a single material according to size requirements.

Step S41: The operator will select the material that has completed the molding process to attach a high-temperature tape on a backside of the material to facilitate fixation and subsequent cutting, and then attach the material attached with the high temperature tape to the plate fixture on a reverse side, and ensure the hole position of the supporting plate on the material is aligned with the hole position of the plate fixture, so that the precise size and shape can be obtained during cutting.

Step S42: Prepare a piece of base film in advance and place it between the material and the fixture that have been aligned with the hole positions to ensure that the base film is tightly bonded to the material and the high temperature tape, and use a cloth to smooth out the air and unevenness between the base film and the material at the same time, so as to enhance the bonding effect.

Step S43: Perform precise cutting operation on the material that has been attached to the high temperature tape and secured to the fixture, and after finishing cutting, uses an air gun to quickly dry any moisture that may be present on the surface of the material, and to strip off the excess scraps.

Step S44: Remove the cut material from the high temperature tape with the aid of the fixture, and put the material into a sieve shaker to further remove the leftover scraps, so as to ensure the cleanliness and uniform specification of the product.

Step S45: After finishing the above steps, the selected material will enter a polishing process to trim surfaces of the material by a polishing machine, thus to ensure that the surfaces are smooth and flat. After polishing, the material will be cleaned to remove impurities such as abrasive debris. After cleaning, the material will be put into an oven for dehumidification treatment to ensure that the internal moisture of the material is effectively removed. Finally, the material after being dehumidified will be properly stored in a moisture-proof cabinet for subsequent steps.

A fifth process: light splitting, for splitting light in the material having been cut according to customers' requirements.

Step S51: Sort out the LED lamp bead materials that have been cut, polished and cleaned to ensure that they are clean and dust-free, a box of the light splitter needs to be cleaned out before it starts to work, removing any residual debris inside the machine or product fragments from the previous batch, and at the same time, carefully cleaning the surface of the machine to prevent mixing of different batches or different specifications, which will affect the accuracy of the splitting results.

Step S52: According to the specific requirements and standards of customers, set the parameters of the splitter, such as spectral range, brightness level, color consistency, etc., thus to ensure that the LED lamp beads that meet the specifications can be accurately distinguished and screened out. After the material sorting is completed, the qualified LED lamp beads are put into an electrostatic bag one by one for packaging. The electrostatic bag can effectively prevent the damages caused by electrostatic to the LED lamp beads and help keep them dry. The packaged lamp beads should be quickly stored in a moisture-proof cabinet to prevent moisture from affecting product quality. After the light splitting process is completed, these lamp beads can be transferred to the next step for further processing or packing and shipping.
a sixth process: braiding, packaging and shipping.

Step S61: The LED lamp bead material that meets the specifications after light splitting process is transferred to an archived area for classification and archiving, and the lamp beads with the same parameters are put into the same material box, which is convenient for management and subsequent automatic operations, and the sorted archived materials are loaded onto a braiding machine.

Step S62: Before starting the braiding operation, the braiding machine is completely cleaned to ensure that there are no impurities and dust inside the machine, so as to prevent affections on the quality of the lamp beads and the braiding effect. Then, the archived LED lamp beads material is poured into a circular vibrating plate and arranged evenly through vibration, then the braiding operation is started, and the lamp beads are fixed on a carrier belt in an orderly manner. The material having been completed braiding operation is pasted with a corresponding product label on a reel, which indicates important information such as product model, parameters, and quantity.

Step S63: After the braiding machine completes the braiding operation of a roll of the material, it is scanned and archived to ensure that the data is accurate, and then the LED lamp bead reel in a full braiding roll will be loaded into a special aluminum foil bag to further strengthen the moisture-proof and anti-static protections. Finally, the aluminum foil bag having been packaged is put into a carton box for storage operation. At this step, the LED lamp beads have completed the whole processes from production to packaging, and can be ready for shipment to customers.

### Comparison Example I

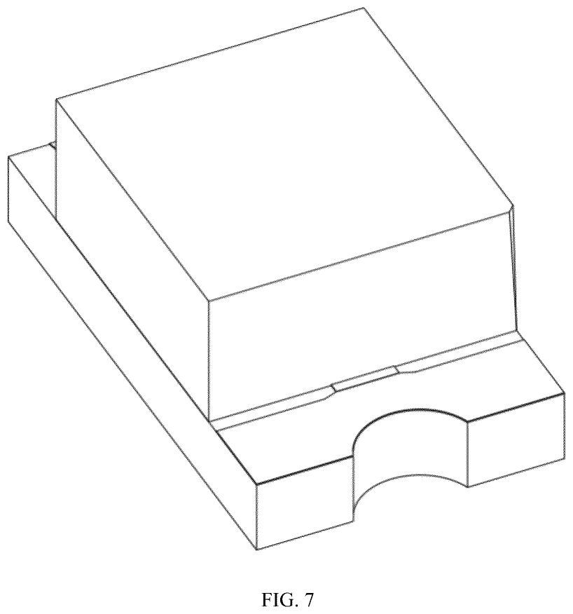

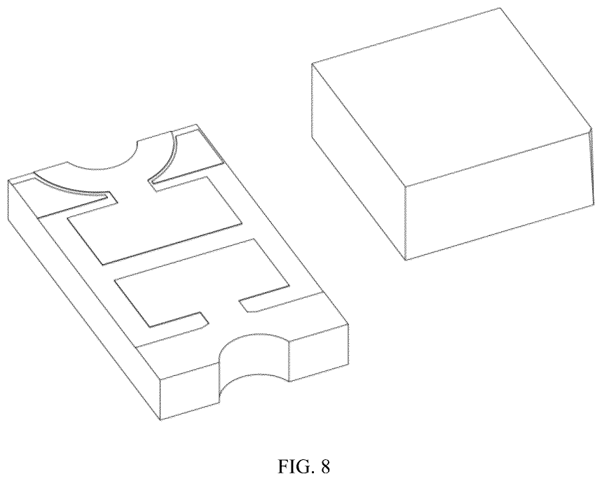

As shown in FIGS. 7 to 8, a traditional LED lamp bead generally adopts a design of electrode structure distributed in half, that is, an positive electrode and an negative electrode are located on opposite sides of the bracket 101. an LED chip 104 is provided on one side of the electrode plate when the LED chip 104 is arranged face-up. In order to energize the LED chip 104, the electrode of the LED chip 104 must be connected to the corresponding electrode plate by using a gold wire. At this time, one end of the gold wire is connected from one side of the electrode plate to the other side of the electrode plate across an insulation belt, when the LED chip 104 is packaged, the gold wire must be also packaged, so that no matter how many LED chips 104 are provided on the electrode plate or the LED chips 104 are provided on either side of the electrode plate, the packaging material 105 must cover the electrode plates on both sides when packaging. When the LED chips 104 are in the case of backward mounting, there is no need to use gold wire to weld the LED chips 104 and the electrode plates, but the positive and negative electrodes of the LED chips 104 are in contact with the electrode plates on both sides. When the LED chips 104 are flipped, there is no need to use the gold wire to weld the LED chip 104 and the electrode plates, but the positive and negative electrodes of the LED chip 104 are in contact with the electrode plates on both sides, so the LED chip 104 needs to be installed between the two electrode plates when the LED chip 104 is flipped. Due to the limitation of the installing position of the LED chip 104, when the flipped LED chips 104 are packaged, no matter how many LED chips 104 are provided on the bracket 101, they will be covered by the same packaging material 105. In summary, with the design of the traditional electrode plates, a single LED lamp bead 1 can only be packaged and activated one color of phosphor, so that each chip can only emit a single color of light.

In the chip-type lamp bead capable of emitting polychromatic light of the present disclosure, the first electrode plate 102 and the second electrode plate 103 are not simply laid out in halves, but are configured to be nested on both sides of the bracket 101, and multiple independently packaged LED chips 104 can be fixed and connected to each electrode plates. Each independently packaged LED chip 104 can emit different lights according to the colors of the packaging material 105. The LED chips 104 are connected in parallel with each other, which means that each chip 104 can be independently controlled and lit, so that different colors of light can be emitted from the same lamp bead or more color effects can be produced through mixing.

### Comparison Example II

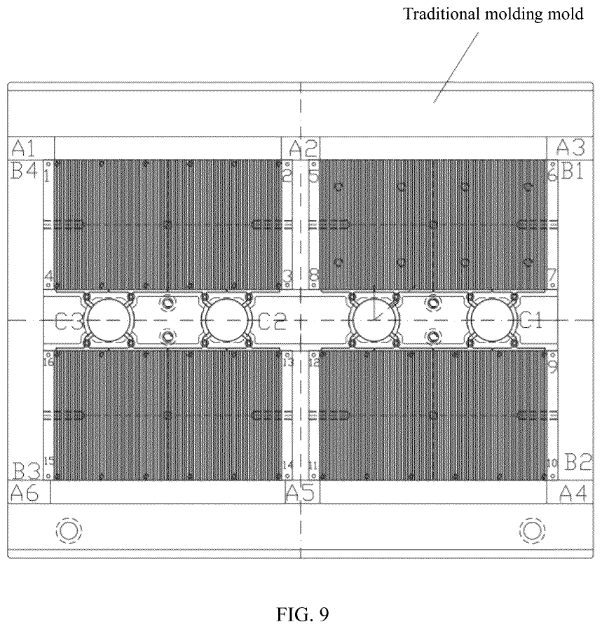

As shown in FIG. 9, a traditional packaging mold has four glue compound placement areas, and the four glue compound placement areas are divided into two pairs. The main glue channels of the same pair of glue compound placement areas are communicated, so two colors of glue powders cannot be operated at the same time.

The placement areas of the glue compound of the molding mold according to the present disclosure are different from each other, so the glue powders of two colors can be operated at the same time.

Combined with the embodiments and the comparison examples, the present disclosure solves the problem that the current chip-type lamp bead bracket can only be molded with one color, and if two colors are needed, the chip is used to emit light, and the packaging material cannot be used for debugging.

The above is only a preferred embodiment of the present disclosure, but the protection scope of the present disclosure is not limited thereto. For those skilled in the art, within the technical scope disclosed in the present disclosure, any equivalent substitutions or changes made in accordance with the technical solutions and its inventive concepts of the present disclosure shall be covered within the scope of protection of the present disclosure.

What is claimed is:

1. A production method for a chip-type lamp bead capable of emitting polychromatic light, wherein the production method comprises the following processes:
a first process: die bonding, for fixing a chip to a supporting plate;
a second process: wire bonding, for linking positive and negative electrodes of the chip to the bracket;
a third process: molding, for packaging the material with an epoxy resin after die bonding and wire bonding, wherein different light colors are achieved through matching with different phosphors;
a fourth process: cutting, for cutting the molded material into a single material according to size requirements;
a fifth process: light splitting, for splitting light in the material having been cut according to customers' requirements; and
a sixth process: braiding, packaging and shipping.

2. The production method for the chip-type lamp bead capable of emitting polychromatic light according to claim 1, wherein the first process further comprises the following steps:
ensuring that a special mark, a green oil point, on the supporting plate is accurately identified and ensuring that the first LED chip is fixed according to the predetermined position, that is, the direction of the green oil point in the process of die bonding through a PR (Picture Recognition) technology; wherein the supporting plate is a raw material of the bracket, and multiple brackets are formed after the supporting plate is cut.

3. The production method for the chip-type lamp bead capable of emitting polychromatic light according to claim 1, wherein the third process further comprises the following steps:
an operator receives a made glue compound, and then places it into a mold hole on a ready molding mold; before the molding operation, an upper mold and a lower mold of a molding machine are uniformly sprayed with a part agent to ensure that the packaging material does not adhere to the mold when it is in contact with the mold, so as to facilitate subsequent separation; during the molding operation, the bracket is upended and placed on the lower mold of the molding mold at first, and then the upper mold and the lower mold are pressed and heated to melt the glue compound to form a glue mixture, and the glue mixture flows to and covers the LED chip; when the temperature of molds drops and the glue mixture solidifies, the mold is opened to remove the material.

4. The production method for the chip-type lamp bead capable of emitting polychromatic light according to claim 3, wherein the molding mold comprises a lower mold, the lower mold further comprises a first molding area and a second molding area, and a structure of each part of the second molding area and the first molding area are the same; and the first molding area comprises a first supporting plate placement area and a second supporting plate placement area.

5. The production method for the chip-type lamp bead capable of emitting polychromatic light according to claim 4, wherein the first molding area comprises a first glue compound hole and a second glue compound hole, the first glue compound hole and the second glue compound hole are provided on a top surface of the lower mold, the first glue compound hole is used for placing a first color glue compound, and the second glue compound hole is used for placing a second color glue compound; the first glue compound hole and the second glue compound hole are located between the first supporting plate placement area and the second supporting plate placement area; the lower mold is provided with first main glue channels at both sides of the first glue compound hole; the lower mold is provided with multiple first secondary glue channels at one side of the first main glue channel, the first main glue channel is communicated with the first secondary glue channel; the lower mold is provided with a second main glue channel at both sides of the second glue compound hole, the lower mold is provided with multiple second secondary glue channels at one side of the second main glue channel, and the second main glue channel is communicated with the second secondary glue channel.

6. The production method for the chip-type lamp bead capable of emitting polychromatic light according to claim 5, wherein the lower mold is provided with an exhaust hole at one end of both the first secondary glue channel and the second secondary glue channel.

7. The production method for the chip-type lamp bead capable of emitting polychromatic light according to claim 2, wherein four corners of the supporting plate are provided with positioning holes, the positioning holes are correspondingly placed on the molding mold for preventing the deviation of the bracket, and the positioning holes on both sides of the supporting plate are arranged asymmetrically for preventing the supporting plate from being reversed.

8. The production method for the chip-type lamp bead capable of emitting polychromatic light according to claim 1, wherein a single material cut in the fourth process comprises a LED lamp bead;
where in the LED lamp bead comprises a bracket, the bracket provides a basis for physical support and electrical conduction of the entire LED lamp bead;
where in one side of a top surface of the bracket is fixedly connected with a first electrode plate, the other side of the top surface of the bracket is fixedly connected with a second electrode plate; the first electrode plate and the second electrode plate are configured to be nested with each other, the first electrode plate and the second electrode plate are both fixedly connected with a LED chip, the first electrode plate and the second electrode plate are both electrically connected with the LED chip; a packaging material is fixedly connected on the LED chip, the packaging material is fixedly connected with the bracket, and the packaging material is used for covering and protecting the LED chip.

9. The production method for the chip-type lamp bead capable of emitting polychromatic light according to claim 8, wherein an overall shape of the first electrode plate and the second electrode plate is a L-shape, one end of the first electrode plate faces one side of the second electrode plate, and the other side of the second electrode plate faces the other end of the first electrode plate, and the first electrode plate and the second electrode plate are enclosed to form a rectangle shape.

10. The production method for the chip-type lamp bead capable of emitting polychromatic light according to claim 8, wherein the packaging material is a transparent epoxy resin, and a colored phosphor is mixed into the packaging material.
